(19) United States
(12) Patent Application Publication
(10) Pub. No.: US 2010/0328797 A1
(43) Pub. Date: Dec. 30, 2010

(54) DISPLAY FILTER

(75) Inventors: Ji Young Kim, ChungCheongNam-Do (KR); Ji Yoon Seo, ChungCheongNam-Do (KR); Jong Taek Kim, ChungCheongNam-Do (KR); Dae Chul Park, ChungCheongNam-Do (KR)

Correspondence Address: LERNER, DAVID, LITTENBERG,;KRUMHOLZ & MENTLIK, 600 SOUTH AVENUE WEST, WESTFIELD, NJ, 07090, US

(73) Assignee: SAMSUNG CORNING PRECISION GLASS CO., LTD., Gyeongsangbuk-do (KR)

(21) Appl. No.: 12/822,604

(22) Filed: Jun. 24, 2010

(30) Foreign Application Priority Data
Jun. 26, 2009 (KR) 10-2009-0057572

(51) Int. Cl. G02B 5/20; H05K 9/00

(52) U.S. Cl. 359/892; 174/389

(57) ABSTRACT

A display filter includes a base substrate disposed in front of a display module, an optical film laminated on the surface of the base substrate that faces a user, and a hard coating layer formed on the surface of the base substrate that faces the display module. The hard coating layer prevents the base substrate from being deformed.

### CROSS REFERENCE TO RELATED APPLICATION

The present application claims priority from Korean Patent Application Number 10-2009-0057572 filed on Jun. 26, 2009, the entire contents of which is incorporated herein for all purposes by this reference.

### BACKGROUND OF THE INVENTION

1. Field of the Invention

The present invention relates to a display filter and, more particularly, to a display filter that obtains excellent optical performance and image quality even in hot or humid environments, has excellent durability, and is capable of preventing buildup of static electricity.

2. Description of Related Art

In response to the emergence of the advanced information society, components and devices related to image displays have been significantly improved and rapidly distributed. Among them, display devices, which display images, have been widely distributed for use in TVs, Personal Computer (PC) monitors and the like. Moreover, attempts are underway to simultaneously increase the size and reduce the thickness of such display devices.

In general, a Plasma Display Panel (PDP) device is gaining attention since it can achieve a large size and a thin thickness when compared to a Cathode Ray Tube (CRT) device, which was representative of conventional display devices.

The PDP device displays an image using gas discharge, and has excellent display properties, namely: display capability, luminance, contrast, after-image characteristics, viewing angle, and the like. In addition, the PDP device is a light-emitting display device that can easily be made to have a large size and a thin thickness and is considered to have characteristics suitable for a high quality digital TV in the future.

Such a PDP device generates electric discharge from gas between electrodes by applying a direct or alternating voltage to the electrodes. The electric discharge causes ultraviolet (UV) radiation, which in turn activates phosphor, thereby emitting light.

However, due to these operating characteristics, the PDP device has drawbacks, such as a large amount of Electro-Magnetic Interference (EMI) and Near-Infrared (NIR) radiation emitted therefrom, and orange light emitted from the gas contained therein, such as He or Xe, and causing color purity to deteriorate. In addition, EMI and NIR radiation are harmful to the human body and may cause precision devices, such as a mobile phone and a remote control, to malfunction.

Therefore, there is a demand to reduce the emission of EMI and NIR radiation from the PDP device to a certain value or less. For this, the PDP device employs a PDP filter that has a variety of functions, such as EMI shielding, NIR shielding, anti-reflection, and/or color purity improvement, in order to block EMI and NIR radiation, reduce the reflection of light, and improve color purity.

FIG. 1 is a cross-sectional view schematically showing a PDP filter of the related art. As shown in the figure, the PDP filter of the related art includes an antireflection layer 11, a transparent substrate 12, an electromagnetic interference shielding layer 13, a color correction layer 14, and a base substrate 15.

The anti-reflection layer 120 improves visibility by reducing the reflection of external light. The transparent substrate 12 supports the anti-reflection layer 11, the EMI shielding layer 13, the color correction layer 14, and the base substrate 15, which are laminated thereon. The transparent substrate 12 can be made of an annealed glass or a transparent resin. The EMI shielding layer 13 blocks the harmful electromagnetic wave emitted from the PDP device. The color correction layer 14 serves to alter or correct the color balance by reducing or adjusting the amounts of Red (R), Green (G), and Blue (B) light. The color correction layer 14 can include a colorant that can block NIR radiation. The color correction layer may be formed as a coating layer formed on the base substrate. In this case, the base substrate 15 serves to support and protect the color correction layer 14. The base substrate may be made of Polyethylene Terephthalate (PET) or Triacetyl Cellulose (TAC).

However, this PDP filter of the related art has the problem of degrading image quality, which defeats its purpose. For example, when the display device is exposed to high temperature, high humidity, or the like, visibility degradation occurs due to the elution of oligomer, one of the materials of the PET base substrate, from the surface. In addition, the PDP filter also has the problem of corrosion of a conductive film, which is used to block electromagnetic wave, due to the exposure to the high-humidity conditions. Meanwhile, the PDP filter of the related art also has the problem that static electricity is built up on a surface of the filter, so that dust clings to the filter and thus visibility deteriorates.

The information disclosed in this Background of the Invention section is only for the enhancement of understanding of the background of the invention, and should not be taken as an acknowledgment or any form of suggestion that this information forms a prior art that would already be known to a person skilled in the art.

### BRIEF SUMMARY OF THE INVENTION

Various aspects of the present invention provide a display filter that can improve the visibility of a display device by preventing a base substrate from being deformed.

Also provided is a display filter that can prevent an optical film formed on a base substrate from being deformed even when exposed to high-humidity conditions.

Also provided is a display filter that can prevent visibility from deteriorating due to static electricity.

In an aspect of the present invention, the display filter includes a base substrate disposed in front of a display module, an optical film formed on the surface of the base substrate that faces a user, and a hard coating layer formed on the surface of the base substrate that faces the display module. The hard coating layer prevents the base substrate from being deformed.

According to an exemplary embodiment of the invention, the hard coating layer may have a thickness ranging from 1 μm to 3 μm.

In another aspect of the present invention, the hard coating layer may include an antistatic substance that prevents static electricity from being built up on the surface.

According to the exemplary embodiments of the present invention as set forth above, the display filter can advantageously prevent substances of the base substrate from eluting from the surface of the base substrate, particularly, oligomer having a small molecular weight from eluting from the surface of the base substrate, and preventing visibility from being lowered due to the elution of oligomer, by virtue of the hard coating layer that prevents the base substrate from being deformed in hot and humid environments.

In addition, the display filter can advantageously satisfy scratch resistance requirements and lower the moisture permeation rate of the base substrate, by virtue of the hard coating layer, thereby preventing the optical film, formed on the base substrate, from being deformed.

Furthermore, the display filter can advantageously prevent the visibility of a display device with the display filter from deteriorating due to buildup of static electricity, by means of the antistatic substance contained in the hard coating layer.

The methods and apparatuses of the present invention have other features and advantages which will be apparent from, or are set forth in more detail in the accompanying drawings, which are incorporated herein, and in the following Detailed Description of the Invention, which together serve to explain certain principles of the present invention.

### BRIEF DESCRIPTION OF THE DRAWINGS

FIG. 1 is a cross-sectional view schematically showing a PDP filter of the related art; and

FIG. 2 is a cross-sectional view schematically showing the structure of a display device to which a display filter according to an exemplary embodiment of the invention is applied.

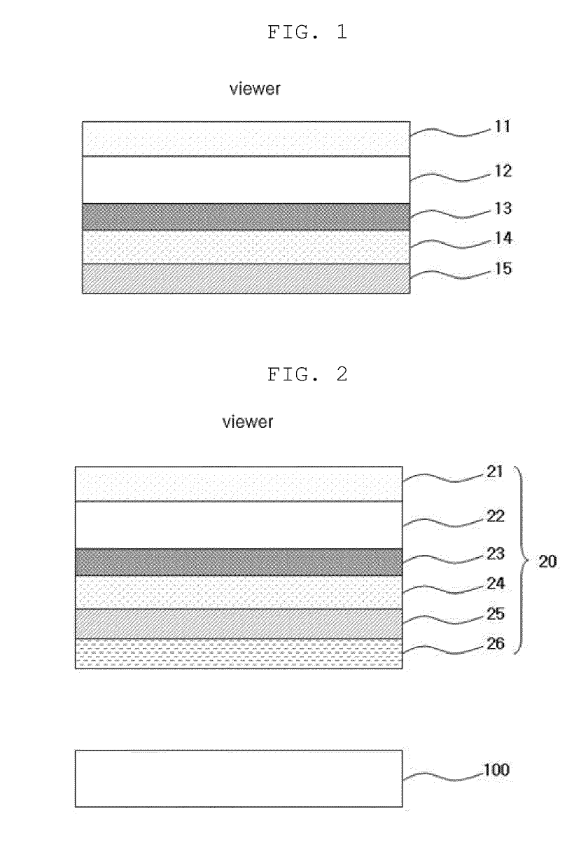

### DETAILED DESCRIPTION OF THE INVENTION

Reference will now be made in detail to various embodiments of the present invention(s), examples of which are illustrated in the accompanying drawings and described below, so that the scope of the invention can be fully conveyed to a person of ordinary skill in the art. While the invention(s) will be described in conjunction with exemplary embodiments, it will be understood that the present description is not intended to limit the invention(s) to those exemplary embodiments. On the contrary, the invention(s) is/are intended to cover not only the exemplary embodiments, but also various alternatives, modifications, equivalents and other embodiments that may be included within the spirit and scope of the invention as defined by the appended claims.

FIG. 2 is a cross-sectional view schematically showing the structure of a display device to which a display filter according to an exemplary embodiment of the invention is applied. Here, the display device may be a Plasma Display Panel (PDP) device. As shown in FIG. 2, the display filter 20 is installed in front of the display module 100.

The display filter 20 of this embodiment can include a transparent substrate 22, an optical film including an anti-reflection layer 21, an EMI shielding layer 23 and an NIR shielding layer 24, a base substrate 25, and a hard coating layer 26.

The anti-reflection layer 21 improves visibility by reducing the reflection of external light. The anti-reflection layer 21 can be formed as a thin film of transparent fluorine-based polymer resin, magnesium fluoride, silicon-based resin, or silicon oxide, which has a low refractive index of 1.5 or less, preferably 1.4 or less, in the visible wavelength range. Here, the anti-reflection layer 21 can be formed as a single layer with the thickness of, for example, one quarter of a wavelength of light.

In addition, the anti-reflection layer 21 can have a multi-layer structure that includes two or more layers of thin films having different refractive indices. The thin films can be made of an inorganic compound, such as metal oxide, fluoride, silicide, boride, carbide, nitride, sulfide, or the like, or an organic compound, such as silicon-based resin, acrylic resin, fluorine-based resin, or the like.

The transparent substrate 22 is the substrate on which the optical film is laminated, and can be made of an annealed glass or a transparent polymer resin. Examples of the transparent polymer resin may include Polyetylene Terephthalate (PET), acryl, Polycabonate (PC), urethane acrylate, polyester, epoxy acrylate, brominate acrylate, Polyvinyl Chloride (PVC), and the like.

The EMI shielding layer 23 serves to block electromagnetic wave emitted from the display module 100, which is harmful to the human body. In an example thereof, the EMI shielding layer 23 can be formed as a multilayer transparent conductive film by laminating metal thin films and high-refractive-index transparent thin films. In another example thereof, the EMI shielding layer 23 can be formed to include a conductive mesh. It is possible to perform both the NIR shielding function and the EMI shielding function by using only the multilayer transparent conductive film without a separate NIR shielding layer 24.

The NIR shielding layer 24 serves to block NIR radiation, which would otherwise cause electronic devices, such as a mobile phone or a remote control, to malfunction. The material that can absorb NIR radiation may be one or more selected from among mixed colorants of Ni complex and diimonium, compound colorants containing Cu ions and Zn ions, cyanine-based colorants, anthraquinone-based colorants, squarylium-based compounds, azomethine-based compounds, oxysonol compounds, azo-based compounds, benzylidene-based compounds, and the like. The NIR shielding layer can be formed as a coating layer on the base substrate. In this case, the film consisting of the NIR shielding layer, the base substrate and the hard coating layer may be adhered onto the EMI shielding layer by means of adhesive.

The base substrate 25 is disposed in front of the display module 110, and serves to protect the EMI shielding layer 23 and the NIR shielding layer 24. The base substrate may be made of polymer resin. It is preferred that the base substrate 25 be made of PET.

The hard coating layer 26 is formed by coating the surface of the base substrate 25 that faces the display module. The hard coating layer serves to prevent the base substrate 25 from being deformed, for example, to prevent oligomer from eluting in high-temperature or high-humidity environments. Here, the hard coating layer can be formed by die coating, spray coating, spin coating, gravure coating, or the like.

Table 1 below presents the results obtained by measuring haze values of display devices in an environment having a temperature of 60° C. and a relative humidity of 90%, in which one of the display devices employed a base substrate I without a hard coating layer and the other one of the display devices employed a base substrate II with a hard coating layer. It is possible to confirm whether or not the hard coating layer 26 has the function of preventing the deformation of the base substrate 25, for example, the elution of oligomer, referring to the measured haze values of the display devices.

TABLE 1

| | Before test | After test | Variance |
|---|---|---|---|
| Base substrate I | 0.56 | 4.27 | 3.71 |
| Base substrate II | 0.52 | 0.72 | 0.2 |

As presented in Table 1 above, it can be appreciated that the display device that employed the base substrate II, having the hard coating layer, had good visibility. Accordingly, it can be confirmed that the hard coating layer 26 has the effect of preventing oligomer elution from the base substrate 25.

In an exemplary embodiment, the hard coating layer 26 can be made of an acrylic substance. Examples of this acrylic substance may include polyester acrylate, urethane acrylate, epoxy acrylate, or the like. Since poly-acrylic materials have a water-absorbing characteristic, the hard coating layer 26 can lower the water transmittance through the base substrate 25 by absorbing water. This, as a result, can prevent the EMI shielding layer 25, including a conductive film or a metal mesh, from corroding.

Table 2 below presents the results obtained by measuring moisture contents (g/m²) of the base substrate I without the hard coating layer and the base substrate II with the hard coating layer, in an environment having a temperature of 25° C. and a relative humidity of 60%.

TABLE 2

| | Before test | After test | Variance |
|---|---|---|---|
| Base substrate I | 216.473 | 217.3543 | 0.88126 |
| Base substrate II | 215.8837 | 216.79 | 0.90628 |

As presented in Table 2 above, it can be appreciated that the base substrate II with the hard coating layer had a low level of moisture content. Accordingly, it can be confirmed that the permeation rate of moisture into the base substrate II was lowered by the hard coating layer.

Table 3 below presents the results obtained by measuring the relationships between the thickness of a hard coating layer and the moisture content (g/m²), in an environment having a temperature of 25° C. and a relative humidity of 60%.

TABLE 3

| Thickness of hard | | | |
|---|---|---|---|
| coating layer (μm) | Before test | After test | Variance |
| 1.0 | 211.70534 | 213.13704 | 1.4317 |
| 2.0 | 211.53576 | 213.1704 | 1.63464 |
| 3.0 | 210.8352 | 212.53934 | 1.70413 |
| 4.0 | 211.9194 | 213.61242 | 1.69302 |

As presented in Table 3 above, it is preferred that the hard coating layer have a thickness from 1 μm to 3 μm. If the thickness of the hard coating layer is less than 1 μm, it is impossible to prevent oligomer from eluting from the base substrate in the hot and humid conditions. On the other hand, it can be confirmed that, if the thickness of the hard coating layer exceeds 3 μm, the moisture blocking effect is smaller than that when the thickness is 3 μm although it is possible to prevent oligomer from eluting from the base substrate.

In another embodiment, the hard coating layer 26 can include an antistatic substance, which prevents buildup of static electricity on the surface of the base substrate 25. Here, the antistatic substance may be a metal oxide such as SnO₂ or SbO₂. As another example, the antistatic substance may be a conductive polymer.

Herein, only the PDP device has been described as the display device to which the display filter according to an exemplary embodiment of the invention is applied. However, the display filter according to an exemplary embodiment of the invention can also be applied to a Liquid Crystal Display (LCD) device, an Organic Light Emitting Display (OLED) device, etc.

The foregoing descriptions of specific exemplary embodiments of the present invention have been presented for the purposes of illustration and description, so that the scope of the invention can be fully conveyed to a person of ordinary skill in the art. They are not intended to be exhaustive or to limit the invention to the precise forms disclosed, and obviously many modifications and variations are possible in light of the above teachings. The exemplary embodiments were chosen and described in order to explain certain principles of the invention and their practical application, to thereby enable the person of ordinary skill in the art to make and utilize various exemplary embodiments of the present invention, as well as various alternatives and modifications thereof. It is intended that the scope of the invention be defined by the Claims appended hereto and their equivalents.

What is claimed is:

1. A display filter used in a display device which includes a display module installed therein,
a base substrate disposed in front of the display module;
an optical film formed on a surface of the base substrate which faces a viewer; and
a hard coating layer coating a surface of the base substrate which faces the display module, to prevent the base substrate from being deformed.

2. The display filter according to claim 1, wherein the hard coating layer contains an antistatic substance that prevents static electricity from being built up on the base substrate.

3. The display filter according to claim 1, wherein the hard coating layer has a thickness from 1 μm to 3 μm.

4. The display filter according to claim 1, wherein the base substrate comprises polyethylene terephthalate.

5. The display filter according to claim 1, wherein the optical film comprises an electromagnetic interference shielding layer, wherein the electromagnetic interference shielding layer comprises a multilayer transparent conductive film of metal thin films and high-refractive-index transparent thin films or a conductive mesh.

6. The display filter according to claim 1, wherein the hard coating layer comprises acrylic compound.
